(19) United States
(12) Patent Application Publication
(10) Pub. No.: US 2018/0294397 A1
(43) Pub. Date: Oct. 11, 2018

(54) THERMOELECTRIC CONVERSION DEVICE

(71) Applicant: FUJIFILM Corporation, Tokyo (JP)

(72) Inventors: Hideyuki SUZUKI, Kanagawa (JP); Shinji IMAI, Kanagawa (JP)

(73) Assignee: FUJIFILM Corporation, Tokyo (JP)

(21) Appl. No.: 15/992,974

(22) Filed: May 30, 2018

Related U.S. Application Data
(63) Continuation of application No. PCT/JP2016/087095, filed on Dec. 13, 2016.

(30) Foreign Application Priority Data
Dec. 25, 2015 (JP) 2015-253399

(51) Int. Cl. H01L 35/30; H01L 35/04; H01L 35/32

(52) U.S. Cl. CPC H01L 35/30; H01L 35/32; H01L 35/04

(57) ABSTRACT

Provided is a thermoelectric conversion device including a plurality of thermoelectric conversion modules each of which has an insulating support having flexibility, a plurality of p-type thermoelectric conversion layers and n-type thermoelectric conversion layers which are alternately formed on one surface of the support with intervals, and connection electrodes each of which electrically connects the p-type thermoelectric conversion layer and the n-type thermoelectric conversion layer adjacent to each other on the support, and is formed in a bellows structure by being alternately mountain-folded or valley-folded at a position of the connection electrode between the p-type thermoelectric conversion layer and the n-type thermoelectric conversion layer adjacent to each other in one direction, in which the plurality of thermoelectric conversion modules are laminated such that mountain fold portions of one thermoelectric conversion module and valley fold portions of a thermoelectric conversion module adjacent to the one thermoelectric conversion module are overlapped with each other as viewed from a longitudinal direction of the support.

### CROSS-REFERENCE TO RELATED APPLICATIONS

This application is a Continuation of PCT International Application No. PCT/JP2016/087095 filed on Dec. 13, 2016, which claims priority under 35 U.S.C. § 119(a) to Japanese Patent Application No. 2015-253399 filed on Dec. 25, 2015. The above application is hereby expressly incorporated by reference, in its entirety, into the present application.

### BACKGROUND OF THE INVENTION

### 1. Field of the Invention

The present invention relates to a thermoelectric conversion device.

### 2. Description of the Related Art

Thermoelectric conversion materials capable of converting heat energy to electrical energy and vice versa are used in thermoelectric conversion elements such as power generation elements or Peltier elements which generate power using heat.

Thermoelectric conversion elements are capable of directly converting heat energy to electric power and, advantageously, do not require any movable portions.

As a thermoelectric conversion element, a so-called π-type thermoelectric conversion element using a thermoelectric conversion material such as Bi-Te has been known.

A π-type thermoelectric conversion element has a configuration in which a pair of electrodes which are separated from each other is provided, an n-type thermoelectric conversion layer formed of an n-type thermoelectric conversion material is provided on one electrode, while a p-type thermoelectric conversion layer formed of a p-type thermoelectric conversion material is provided on the other electrode, such that the thermoelectric conversion materials are also separated from each other, with the upper surfaces of the two thermoelectric conversion layers being connected by the electrodes.

In addition, a plurality of thermoelectric conversion elements are arranged such that the n-type thermoelectric conversion layer and the p-type thermoelectric conversion layer are alternately arranged, and the electrodes below the thermoelectric conversion layers are connected in series. Thus, a thermoelectric conversion module including a large number of thermoelectric conversion elements is formed.

A problem of a thermoelectric conversion module of the related art is that labor for the production of connecting a large number of thermoelectric conversion layers in series is considerably large. In addition, due to the influence of thermal distortion caused by a difference in thermal expansion coefficient and the occurrence of repeated changes in thermal distortion, a fatigue phenomenon at the interface easily occurs.

As a method for solving such a problem, a thermoelectric conversion module in which a support having flexibility such as a resin film is used is proposed.

This thermoelectric conversion module is configured such that a p-type thermoelectric conversion layer and an n-type thermoelectric conversion layer are alternately arranged on the surface of a support having a flexibility and insulating properties and further, electrodes are formed on the surface of the support so that respective thermoelectric conversion layers are connected in series.

In these thermoelectric conversion modules, for example, after the support is bent or wound in a cylindrical shape, heat conductive plates are arranged in the upper portion and the lower portion to contact the modules with a heat source. In addition, a thermoelectric conversion module is formed by forming films using thermoelectric conversion materials on a support and folding the support while sandwiching the support between heat insulating plates in some cases.

For example, JP2005-328000A discloses a thermoelectric conversion device (thermoelectric conversion module) which has a plurality of thermocouples (thermoelectric conversion layers) that are arranged on an electrically insulating sheet having flexibility while being connected in series is bent at each contact position between the thermocouples to be formed in a waveform shape (refer to FIG. 2). It is described that in this thermoelectric conversion device, the thermocouples generate power by respectively arranging heat exchange sheets in waveform top portions and waveform bottom portions and applying a temperature difference between the top portion and the bottom portion, or a temperature difference is generated between the top portion and the bottom portion by applying a current to the thermocouples (refer to paragraph [0022] and the like).

Here, in a case where the thermoelectric conversion module formed by connecting the plurality of thermoelectric conversion elements as described above is used for cooling or heating, the one end side of each thermoelectric conversion element in the energizing direction is cooled, while the other end side of each thermoelectric conversion element is heated by energizing the thermoelectric conversion elements, and thus, a temperature gradient is generated in the energizing direction. Therefore, since the one end side of each thermoelectric conversion element in the energizing direction is cooled, while the other end side of each thermoelectric conversion element in the energizing direction is heated, it is possible to generate a temperature difference in the thermoelectric conversion module.

The thermoelectric conversion efficiency of the thermoelectric conversion module greatly depends on the material of the thermoelectric conversion layer. Therefore, it is possible to increase a temperature difference that can be generated by selecting a material having higher thermoelectric conversion efficiency as the material of the thermoelectric conversion layer or the like. However, it is difficult to obtain a larger temperature difference only by appropriately selecting the material of the thermoelectric conversion layer.

Here, JP2006-237146A discloses a cascade module for thermoelectric conversion in which thermoelectric conversion modules having a it-type structure formed by sequentially connecting one end portions and connecting the other end portions of P-type and N-type thermoelectric conversion elements, which are alternately arranged, by module electrodes are arranged in a laminated manner in a direction of temperature gradient.

Since a configuration in which a plurality of thermoelectric conversion modules are laminated in a direction of temperature gradient as described above makes it possible to obtain a predetermined temperature difference in each thermoelectric conversion module, it is possible to obtain a temperature difference for the number of laminated layers as a whole.

### SUMMARY OF THE INVENTION

However, according to examinations of the present inventors, it has been found that in a case of a configuration in which a plurality of thermoelectric conversion modules having π-type thermoelectric conversion elements are laminated in multistage as disclosed in JP2006-237146A, a temperature loss is generated at the overlapped position and thus a temperature difference for the number of laminated layers cannot be obtained.

As described above, the π-type thermoelectric conversion element has a π-type configuration in which the upper surfaces of two thermoelectric conversion layers provided to be separated from each other are connected by electrodes. Therefore, in the configuration in which the thermoelectric conversion modules having the π-type thermoelectric conversion elements are laminated in the direction of temperature gradient, there is a concern of the π-type structure being damaged due to a pressing force in the lamination direction or the like.

On the other hand, a configuration in which a plurality of thermoelectric conversion modules each formed in a waveform shape by arranging a plurality of thermoelectric conversion layers on a support having flexibility and folding the support at the contact position between the thermoelectric conversion layers are laminated is not disclosed.

An object of the present invention is to solve such problems in the related art and to provide a thermoelectric conversion device having a high mechanical strength and capable of obtaining a sufficient temperature difference by reducing a temperature loss at an overlapped position in a configuration in which a plurality of thermoelectric conversion modules are laminated.

As a result of conducting intensive examinations to solve such problems, the present inventors have found that the above problems can be solved by providing a plurality of thermoelectric conversion modules each of which has an insulating support having flexibility, a plurality of p-type thermoelectric conversion layers and n-type thermoelectric conversion layers which are alternately formed on one surface of the support with intervals, and connection electrodes each of which electrically connects the p-type thermoelectric conversion layer and the n-type thermoelectric conversion layer adjacent to each other, and is formed in a bellows structure by being alternately mountain-folded or valley-folded at a position of the connection electrode between the p-type thermoelectric conversion layer and the n-type thermoelectric conversion layer adjacent to each other in one direction, in which the plurality of thermoelectric conversion modules are laminated such that mountain fold portions of one thermoelectric conversion module and valley fold portions of a thermoelectric conversion module adjacent to the one thermoelectric conversion module are overlapped with each other as viewed from a folding direction of the bellows structure, and thus have completed the present invention.

That is, the present invention provides a thermoelectric conversion device having the following configurations.

(1) A thermoelectric conversion device comprising: a plurality of thermoelectric conversion modules each of which has an insulating support having flexibility, a plurality of p-type thermoelectric conversion layers and n-type thermoelectric conversion layers which are alternately formed on one surface of the support with intervals, and connection electrodes each of which electrically connects the p-type thermoelectric conversion layer and the n-type thermoelectric conversion layer adjacent to each other, and is formed in a bellows structure by being alternately mountain-folded or valley-folded at a position of the connection electrode between the p-type thermoelectric conversion layer and the n-type thermoelectric conversion layer adjacent to each other in one direction,

in which the plurality of thermoelectric conversion modules are laminated such that mountain fold portions of one thermoelectric conversion module and valley fold portions of a thermoelectric conversion module adjacent to the one thermoelectric conversion module are overlapped with each other as viewed from a folding direction of the bellows structure.

(2) The thermoelectric conversion device according to (1), in which the laminated thermoelectric conversion modules are laminated such that the connection electrodes of the mountain fold portions of the thermoelectric conversion module of a lower stage and the connection electrodes of the valley fold portions of the thermoelectric conversion module of an upper stage are overlapped with each other as viewed from the folding direction.

(3) The thermoelectric conversion device according to (1) or (2), further comprising: a pressing member which presses overlapped portions of the mountain fold portions of the thermoelectric conversion module of the lower stage and the valley fold portions of the thermoelectric conversion module of the upper stage of the laminated thermoelectric conversion modules in the folding direction.

(4) The thermoelectric conversion device according to (3), in which the pressing member is a frame-like member.

(5) The thermoelectric conversion device according to (3), in which the plurality of thermoelectric conversion modules respectively have through-holes in the overlapped portions, the pressing member is a wire-like member, and the wire-like member is inserted into the through-holes of the plurality of thermoelectric conversion modules.

(6) The thermoelectric conversion device according to any one of (1) to (5), in which a material for forming a thermoelectric conversion layer of the thermoelectric conversion module of the upper stage and a material for forming a thermoelectric conversion layer of the thermoelectric conversion module of the lower stage have different temperature properties.

(7) The thermoelectric conversion device according to any one of (1) to (6), in which the thermoelectric conversion module has the support which is long, a plurality of p-type thermoelectric conversion layers and n-type thermoelectric conversion layers which are alternately formed on one surface of the support with intervals in a longitudinal direction of the support, and connection electrodes each of which electrically connects the p-type thermoelectric conversion layer and the n-type thermoelectric conversion layer adjacent to each other in the longitudinal direction of the support, and is formed in a bellows structure by being alternately mountain-folded or valley-folded at the position of the connection electrode between the p-type thermoelectric conversion layer and the n-type thermoelectric conversion layer adjacent to each other.

(8) The thermoelectric conversion device according to any one of (1) to (6), in which in the thermoelectric conversion module, one or more p-type thermoelectric conversion layers and one or more n-type thermoelectric conversion layers are arranged in a region between adjacent mountain and valley folds in a direction orthogonal to the folding direction.

According to the present invention, it is possible to provide a thermoelectric conversion device having a high mechanical strength and capable of obtaining a sufficient temperature difference by reducing a temperature loss at an overlapped position in a configuration in which a plurality of thermoelectric conversion modules are laminated.

### BRIEF DESCRIPTION OF THE DRAWINGS

FIG. 1 is a cross-sectional view conceptually showing an example of a thermoelectric conversion device according to the present invention.

FIG. 2A is a schematic perspective view showing an example of a thermoelectric conversion module used in the present invention.

FIG. 2B is a cross-sectional view taken along line B-B of FIG. 2A.

FIG. 2C is a top view for illustrating the thermoelectric conversion module.

FIG. 2D is a side view of FIG. 2C.

FIG. 3 is a schematic cross-sectional view showing another example of the thermoelectric conversion module.

FIG. 4 is a side view conceptually showing another example of the thermoelectric conversion device according to the present invention.

FIG. 5 is a cross-sectional view conceptually showing still another example of the thermoelectric conversion device according to the present invention.

FIG. 6 is a schematic perspective view for illustrating the thermoelectric conversion device in FIG. 5.

FIG. 7 is a top view for illustrating still another example of the thermoelectric conversion module.

### DESCRIPTION OF THE PREFERRED EMBODIMENTS

Hereinafter, a thermoelectric conversion device of the present invention will be described in detail based on preferable embodiments shown in the accompanying drawings.

In the present specification, a numerical range represented by using “to” indicates a range including the numerical values before and after “to” as the lower limit and the upper limit.

A thermoelectric conversion device of the present invention includes a plurality of thermoelectric conversion modules each of which has an insulating support having flexibility, a plurality of p-type thermoelectric conversion layers and n-type thermoelectric conversion layers which are alternately formed on one surface of the support with intervals, connection electrodes each of which electrically connects the p-type thermoelectric conversion layer and the n-type thermoelectric conversion layer adjacent to each other, and is formed in a bellows structure by being alternately mountain-folded or valley-folded at the position of the connection electrode between the p-type thermoelectric conversion layer and the n-type thermoelectric conversion layer adjacent to each other in one direction,

in which mountain fold portions of one thermoelectric conversion module and valley fold portions of a thermoelectric conversion module adjacent to the one thermoelectric conversion module of the plurality of thermoelectric conversion module are laminated so as to be overlapped with each other as viewed from a folding direction of the bellows structure.

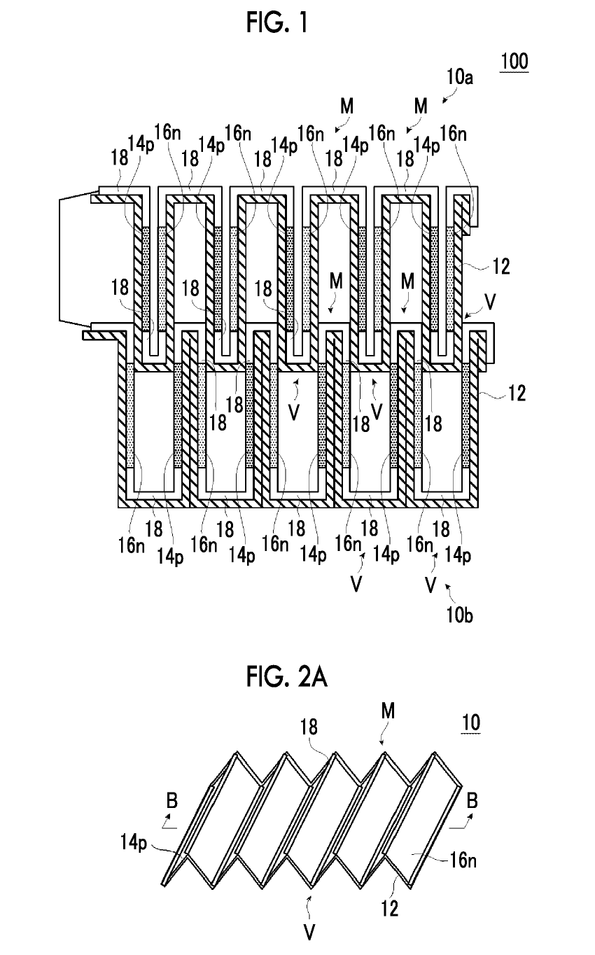

FIG. 1 is a cross-sectional view conceptually showing an example of the thermoelectric conversion device according to the present invention.

A thermoelectric conversion device 100 shown in FIG. 1 has two thermoelectric conversion modules 10a and 10b in which a plurality of thermoelectric conversion elements are formed.

As shown in FIG. 1, the thermoelectric conversion device 100 has a configuration in which a thermoelectric conversion module 10a of an upper stage and a thermoelectric conversion module 10b of a lower stage, which are formed in a bellows structure, are laminated such that valley fold portions V of the thermoelectric conversion module 10a of the upper stage and mountain fold portions M of the thermoelectric conversion module 10b of the lower stage are overlapped with each other as viewed from the folding direction of the bellows structure.

The configuration of the thermoelectric conversion device 100 will be described in detail later.

In the present invention, the folding direction of the bellows structure refers to a direction in which the mountain fold portion and the valley fold portion of the bellows structure of the thermoelectric conversion module are repeated. In the following description, the term “the folding direction of the bellows structure” is also simply referred to as “folding direction”.

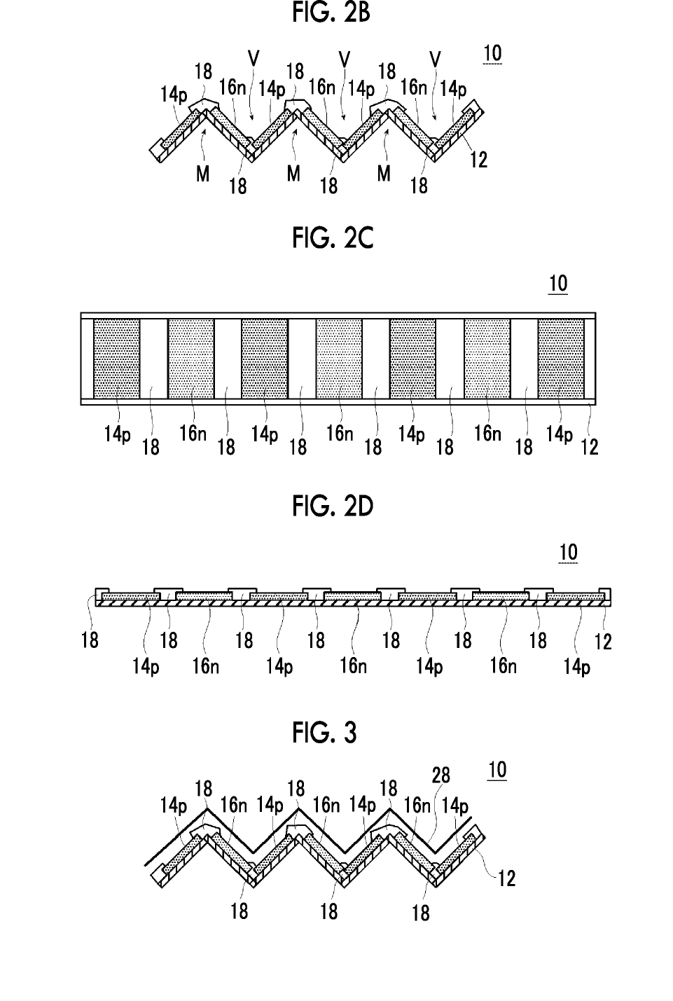

First, using FIGS. 2A to 2D, the thermoelectric conversion modules 10a and 10b will be described. The thermoelectric conversion module 10a of the upper stage and the thermoelectric conversion module 10b of the lower stage have the same configuration except that only the arrangement thereof is different. In the following description, in a case where the thermoelectric conversion module 10a of the upper stage and the thermoelectric conversion module 10b of the lower stage are not required to be distinguished, the both are collectively referred to as “thermoelectric conversion module 10”.

FIG. 2A is a schematic perspective view showing an example of the thermoelectric conversion module 10 used in the present invention, FIG. 2B a cross-sectional view taken along line B-B of FIG. 2A, FIG. 2C is a top view in a state in which the thermoelectric conversion module 10 is spread, and FIG. 2D is a side view of FIG. 2C.

As shown in FIGS. 2A to 2D, in the thermoelectric conversion module 10, connection electrodes 18 having a fixed length are formed on one surface of a long support 12 at fixed intervals in a longitudinal direction of the support 12, and p-type thermoelectric conversion layers 14p and n-type thermoelectric conversion layers 16n having a fixed length are alternately formed on the same surface of the support 12 at fixed intervals in the longitudinal direction of the support 12. One thermoelectric conversion layer and the connection electrodes 18 that are respectively connected to both ends of the thermoelectric conversion layer may form one thermoelectric conversion element.

In the present invention, the length or interval in the longitudinal direction refers to a length or interval in a state in which the thermoelectric conversion module 10 is spread in a plane shape.

In the following description, the term “the longitudinal direction of the support 12” is simply referred to as “longitudinal direction”. As clearly seen from FIG. 2B, the longitudinal direction refers to a horizontal direction in FIG. 2B. The width direction of the support 12 refers to a direction orthogonal to the longitudinal direction.

In addition, in the following description, the term “thermoelectric conversion module 10” is also referred to as “module 10”.

The module 10 is alternately mountain-folded or valley-folded at the position of the connection electrode 18 between the p-type thermoelectric conversion layer 14p and n-type thermoelectric conversion layer 16n adjacent to each other to be parallel to the width direction of the support 12 and is formed in a bellows-like shape. In other words, the width direction of the support 12 refers to a direction orthogonal to the longitudinal direction of the support 12.

The mountain folds and the valley folds are formed in the longitudinal direction at fixed intervals.

In addition, the module 10 has a configuration in which the p-type thermoelectric conversion layers 14p and the n-type thermoelectric conversion layers 16n are alternately connected in series such that a p-type thermoelectric conversion layer 14p is connected to one end portion of the connection electrode 18 at the position of the mountain fold (mountain fold portion M), a n-type thermoelectric conversion layer 16n is connected to the other end portion thereof, another n-type thermoelectric conversion layer 16n is connected to one end portion of the connection electrode 18 at the position of the valley fold (valley fold portion V), and another p-type thermoelectric conversion layer 14p is connected to the other end portion thereof.

Accordingly, the module 10 can be used as a Peltier element which causes a temperature difference between the lower side (valley fold portion V side) and the upper side (mountain fold portion M side) in FIG. 2B by applying a current to the thermoelectric conversion layer.

In addition, the module 10 can be used as a power generation element which generates power by providing a high temperature heat source on the lower side (valley fold portion V side) and a low temperature heat source (heat dissipation means such as a heat dissipation fin) on the upper side (mountain fold portion M side) in FIG. 2B and applying a temperature difference in the vertical direction in FIG. 2B.

Here, a method of preventing a short circuit at the valley portion between the thermoelectric conversion layer and the connection electrode from occurring in the module 10 having a bellows structure is not limited and known methods can be used.

For example, as shown in FIG. 3, an insulating sheet 28 is arranged so as to cover the p-type thermoelectric conversion layers 14p, the n-type thermoelectric conversion layers 16n, and the connection electrodes 18 on the support 12, and the module and the insulating sheet 28 are folded together to form a bellows structure so that a short circuit can be prevented.

As the insulating sheet 28, an insulating sheet having insulating properties capable of preventing a short circuit between the thermoelectric conversion layer and the connection electrode 18 can be suitably used. For the insulating sheet 28, for example, a polyimide can be used.

The support 12 is long and has flexibility and insulating properties.

In the thermoelectric conversion device of the present invention, various long sheet-like materials (films) used in known thermoelectric conversion modules using a flexible support can be used for the support 12 as long as the material has flexibility and insulating properties.

Specific examples thereof include sheet-like materials of polyester resins such as polyethylene terephthalate, polyethylene isophthalate, polyethylene naphthalate, polybutylene terephthalate, poly(1,4-cyclohexylene dimethylene terephthalate), and polyethylene-2,6-naphthalenedicarboxylate, resins such as polyimide, polycarbonate, polypropylene, polyethersulfone, cycloolefin polymer, polyether ether ketone (PEEK), and triacetyl cellulose (TAC), glass epoxy, and liquid crystal polyester.

Among these, from the viewpoint of thermal conductivity, heat resistance, solvent resistance, ease of availability, and economy, sheet-like materials of polyimide, polyethylene terephthalate, polyethylene naphthalate, and the like are suitably used.

Regarding the thickness of the support 12, a thickness which provides sufficient flexibility and functions as the support 12 may be appropriately set according to the material for forming the support 12, and the like.

According to the examinations of the present inventors, the thickness of the support 12 is preferably 25 μm or less and more preferably 13 μm or less.

It is required that the module 10 of the present invention is maintained in a state in which the module is alternately mountain-folded and valley-folded. Although described later, the folding of the module 10 is maintained by the plastic deformation of the connection electrode 18, that is, a metal layer. Here, in a case where the thickness of the support 12 is thick, there is a possibility that the folding of the support 12 may not be maintained by the connection electrode 18. In contrast, the folding of the module 10 can be more suitably maintained by the connection electrode 18 by setting the thickness of the support 12 to 15 μm or less.

In addition, it is preferable to set the thickness of the support 12 to 15 μm or less from the viewpoint of being capable of improving heat utilization efficiency, or the like.

The length and the width of the support 12 may be appropriately set according to the size and the use of the module 10 and the like.

On one surface of the support 12, the p-type thermoelectric conversion layers 14p and the n-type thermoelectric conversion layers 16n having a fixed length are alternately provided at fixed intervals in the longitudinal direction.

In the following description, in a case where the p-type thermoelectric conversion layer 14p and the n-type thermoelectric conversion layer 16n are not required to be distinguished, the both are collectively referred to as “thermoelectric conversion layer”.

In the thermoelectric conversion device of the present invention, for the p-type thermoelectric conversion layer 14p and the n-type thermoelectric conversion layer 16n, various thermoelectric conversion layers formed of various known thermoelectric conversion materials can be used.

As the thermoelectric conversion material constituting the p-type thermoelectric conversion layer 14p and the n-type thermoelectric conversion layer 16n, for example, nickel or a nickel alloy may be used.

As the nickel alloy, various nickel alloys that generate power by causing a temperature difference can be used. Specific examples thereof include nickel alloys mixed with one or two or more of vanadium, chromium, silicon, aluminum, titanium, molybdenum, manganese, zinc, tin, copper, cobalt, iron, magnesium, and zirconium.

In a case where nickel or a nickel alloy is used for the p-type thermoelectric conversion layer 14p and the n-type thermoelectric conversion layer 16n, the nickel content in the p-type thermoelectric conversion layer 14p and the n-type thermoelectric conversion layer 16n is preferably 90% by atom or more and more preferably 95% by atom or more, and the p-type thermoelectric conversion layer 14p and the n-type thermoelectric conversion layer 16n are particularly preferably formed of nickel. The p-type thermoelectric conversion layer 14p and the n-type thermoelectric conversion layer 16n formed of nickel include inevitable impurities.

In a case where a nickel alloy is used as the thermoelectric conversion material for the p-type thermoelectric conversion layer 14p, chromel having nickel and chromium as main components is typically used. In a case where a nickel alloy is used as the thermoelectric conversion material for the n-type thermoelectric conversion layer 16n, constantan having copper and nickel as main components is typically used.

In addition, in a case where nickel or a nickel alloy is used for the p-type thermoelectric conversion layer 14p and the n-type thermoelectric conversion layer 16n and also nickel or a nickel alloy is used for the connection electrode 18, the p-type thermoelectric conversion layer 14p, the n-type thermoelectric conversion layer 16n, the connection electrode 18 may be integrally formed.

As thermoelectric conversion materials that can be used for the p-type thermoelectric conversion layer 14p and the n-type thermoelectric conversion layer 16n, in addition to nickel and nickel alloys, for example, the following materials may be used. Incidentally, the components in parentheses indicate the material composition.

Examples of the materials include BiTe-based materials (BiTe, SbTe, BiSe and compounds thereof), PbTe-based materials (PbTe, SnTe, AgSbTe, GeTe and compounds thereof), Si-Ge-based materials (Si, Ge, SiGe), silicide-based materials (FeSi, MnSi, CrSi), skutterudite-based materials (compounds represented by MX₃ or RM₄X₁₂, where M equals Co, Rh, or Ir, X equals As, P, or Sb, and R equals La, Yb, or Ce), transition metal oxides (NaCoO, CaCoO, ZnInO, SrTiO, BiSrCoO, PbSrCoO, CaBiCoO, BaBiCoO), zinc antimony based compounds (ZnSb), boron compounds (CeB, BaB, SrB, CaB, MgB, VB, NiB, CuB, LiB), cluster solids (B cluster, Si cluster, C cluster, AlRe, AlReSi), and zinc oxides (ZnO).

In addition, for the thermoelectric conversion material used for the p-type thermoelectric conversion layer 14p and the n-type thermoelectric conversion layer 16n, materials that can form a film by coating or printing and can be made into a paste can be used.

Specific examples of such thermoelectric conversion materials include organic thermoelectric conversion materials such as a conductive polymer and a conductive nanocarbon material.

Examples of the conductive polymer include a polymer compound having a conjugated molecular structure (conjugated polymer). Specific examples thereof include known π-conjugated polymers such as polyaniline, polyphenylene vinylene, polypyrrole, polythiophene, polyfluorene, acetylene, and polyphenylene. Particularly, polydioxythiophene can be suitably used.

Specific examples of the conductive nanocarbon material include carbon nanotubes, carbon nanofiber, graphite, graphene, and carbon nanoparticles. These may be used singly or in combination of two or more thereof. Among these, from the viewpoint of further improving thermoelectric conversion properties, carbon nanotubes are preferably used. In the following description, the term “carbon nanotubes” is also referred to as CNTs.

CNT is categorized into single layer CNT of one carbon film (graphene sheet) wound in the form of a cylinder, double layer CNT of two graphene sheets wound in the form of concentric circles, and multilayer CNT of a plurality of graphene sheets wound in the form of concentric circles. In the present invention, each of the single layer CNT, the double layer CNT, and the multilayer CNT may be used singly, or two or more thereof may be used in combination. Particularly, the single layer CNT and the double layer CNT excellent in conductivity and semiconductor characteristics are preferably used, and the single layer CNT is more preferably used.

The single layer CNT may be semiconductive or metallic. Furthermore, semiconductive CNT and metallic CNT may be used in combination. In a case where both of the semiconductive CNT and the metallic CNT are used, a content ratio between the CNTs can be appropriately adjusted. In addition, CNT may contain a metal or the like, and CNT containing fullerene molecules and the like may be used.

An average length of CNT is not particularly limited and can be appropriately selected. Specifically, from the viewpoint of ease of manufacturing, film formability, conductivity, and the like, the average length of CNT is preferably 0.01 to 2,000 μm, more preferably 0.1 to 1,000 μm, and particularly preferably 1 to 1,000 μm, though the average length also depends on an inter-electrode distance.

A diameter of CNT is not particularly limited. From the viewpoint of durability, transparency, film formability, conductivity, and the like, the diameter is preferably 0.4 to 100 nm, more preferably 50 nm or less, and particularly preferably 15 nm or less. Particularly, in a case where the single layer CNT is used, the diameter of CNT is preferably 0.5 to 2.2 nm, more preferably 1.0 to 2.2 nm, and particularly preferably 1.5 to 2.0 nm.

The CNT contains defective CNT in some cases. Because the defectiveness of the CNT deteriorates the conductivity of the thermoelectric conversion layer, it is preferable to reduce the amount of the defective CNT. The amount of defectiveness of the CNT can be estimated by a G/D ratio between a G band and a D band in a Raman spectrum. In a case where the G/D ratio is high, a material can be assumed to be a CNT material with a small amount of defectiveness. The G/D ratio is preferably 10 or higher and more preferably 30 or higher.

In addition, modified or treated CNT can also be used. Examples of the modification or treatment method include a method of incorporating a ferrocene derivative or nitrogen-substituted fullerene (azafullerene) into CNT, a method of doping CNT with an alkali metal (potassium or the like) or a metallic element (indium or the like) by an ion doping method, and a method of heating CNT in a vacuum.

In a case where CNT is used, in addition to the single layer CNT or the multilayer CNT, nanocarbons such as carbon nanohorns, carbon nanocoils, carbon nanobeads, graphite, graphene, amorphous carbon, and the like may be contained in the composition.

In a case where CNT is used for the p-type thermoelectric conversion layer 14p and the n-type thermoelectric conversion layer 16n, it is preferable that the thermoelectric conversion layers include a p-type dopant or an n-type dopant.

### p-Type Dopant

Examples of the p-type dopant include halogen (iodine, bromine, or the like), Lewis acid (PF₅, AsF₅, or the like), protonic acid (hydrochloric acid, sulfuric acid, or the like), transition metal halide (FeCl₃, SnCl₄, or the like), a metal oxide (molybdenum oxide, vanadium oxide, or the like), and an organic electron-accepting material. Examples of the organic electron-accepting material suitably include a tetracyanoquinodimethane (TCNQ) derivative such as 2,3,5,6-tetrafluoro-7,7,8,8-tetracyanoquinodimethane, 2,5-dimethyl-7,7,8,8-tetracyanoquinodimethane, 2-fluoro-7,7,8,8-tetracyanoquinodimethane, or 2,5-difluoro-7,7,8,8-tetracyanoquinodimethane, a benzoquinone derivative such as 2,3-dichloro-5,6-dicyano-p-benzoquinone or tetrafluoro-1,4-benzoquinone, 5,8H-5,8-bis(dicyanomethylene)quinoxaline, dipyrazino[2,3-f:2′,3′-h]quinoxaline-2,3,6,7,10,11-hexacarbonitrile, and the like.

Among these, from the viewpoint of the stability of the materials, the compatibility with CNT, and the like, organic electron-accepting materials such as a tetracyanoquinodimethane (TCNQ) derivative or a benzoquinone derivative is suitably exemplified.

The p-type dopant and the n-type dopant may be used singly or in combination of two or more thereof.

### n-Type Dopant

As the n-type dopant, known materials such as (1) alkali metals such as sodium and potassium, (2) phosphines such as triphenylphosphine and ethylenebis(diphenylphosphine), (3) polymers such as polyvinyl pyrrolidone and polyethylene imine, and the like can be used.

In addition, for examples, polyethylene glycol type higher alcohol ethylene oxide adducts, ethylene oxide adducts of phenol, naphthol or the like, fatty acid ethylene oxide adducts, polyhydric alcohol fatty acid ester ethylene oxide adducts, higher alkylamine ethylene oxide adducts, fatty acid amide ethylene oxide adducts, ethylene oxide adducts of fat, polypropylene glycol ethylene oxide adducts, dimethylsiloxane-ethylene oxide block copolymers, dimethylsiloxane-(propylene oxide-ethylene oxide) block copolymers, fatty acid esters of polyhydric alcohol type glycerol, fatty acid esters of pentaerythritol, fatty acid esters of sorbitol and sorbitan, fatty acid esters of sucrose, alkyl ethers of polyhydric alcohols and fatty acid amides of alkanolamines. Further, acetylene glycol-based and acetylene alcohol-based oxyethylene adducts, and fluorine-based and silicone-based surfactants can be also used.

As the p-type thermoelectric conversion layer 14p and the n-type thermoelectric conversion layer 16n, thermoelectric conversion layers obtained by dispersing the thermoelectric conversion materials in a resin material (binder) are suitably used.

Among these, the thermoelectric conversion layers obtained by dispersing a conductive nanocarbon material in a resin material are more suitably exemplified. Especially, the thermoelectric conversion layer obtained by dispersing CNT in a resin material is particularly suitably exemplified because this makes it possible to obtain high conductivity and the like.

As the resin material, various known nonconductive resin materials (polymer materials) can be used.

Specifically, a vinyl compound, a (meth)acrylate compound, a carbonate compound, an ester compound, an epoxy compound, a siloxane compound, gelatin, and the like may be used.

More specifically, examples of the vinyl compound include polystyrene, polyvinyl naphthalene, polyvinyl acetate, polyvinyl phenol, and polyvinyl butyral. Examples of the (meth)acrylate compound include polymethyl (meth)acrylate, polyethyl (meth)acrylate, polyphenoxy(poly)ethylene glycol (meth)acrylate, and polybenzyl (meth)acrylate. Examples of the carbonate compound include bisphenol Z-type polycarbonate, and bisphenol C-type polycarbonate. Examples of the ester compound include amorphous polyester.

Polystyrene, polyvinyl butyral, a (meth)acrylate compound, a carbonate compound, and an ester compound are preferable, and polyvinyl butyral, polyphenoxy(poly)ethylene glycol (meth)acrylate, polybenzyl (meth)acrylate, and amorphous polyester are more preferable.

In the thermoelectric conversion layer obtained by dispersing a thermoelectric conversion material in a resin material, a quantitative ratio between the resin material and the thermoelectric conversion material may be appropriately set according to the material used, the thermoelectric conversion efficiency required, the viscosity or solid content concentration of a solution exerting an influence on printing, and the like.

In addition, in a case where CNT is used for the p-type thermoelectric conversion layer 14p and the n-type thermoelectric conversion layer 16n, a thermoelectric conversion layer mainly constituted of CNT and a surfactant is also suitably used.

By constituting the thermoelectric conversion layer of CNT and a surfactant, the thermoelectric conversion layer can be formed using a coating composition to which a surfactant is added. Therefore, the thermoelectric conversion layer can be formed using a coating composition in which CNT is smoothly dispersed. As a result, by a thermoelectric conversion layer including a large amount of long and less defective CNT, excellent thermoelectric conversion performance is obtained.

As the surfactant, known surfactants can be used as long as the surfactants function to disperse CNT. More specifically, various surfactants can be used as the surfactant as long as surfactants dissolve in water, a polar solvent, or a mixture of water and a polar solvent and have a group adsorbing CNT.

Accordingly, the surfactant may be ionic or nonionic. Furthermore, the ionic surfactant may be any of cationic, anionic, and amphoteric surfactants.

Examples of the anionic surfactant include an aromatic sulfonic acid-based surfactant such as alkylbenzene sulfonate like dodecylbenzene sulfonate or dodecylphenylether sulfonate, a monosoap-based anionic surfactant, an ether sulfate-based surfactant, a phosphate-based surfactant and a carboxylic acid-based surfactant such as sodium deoxycholate or sodium cholate, and a water-soluble polymer such as carboxymethyl cellulose and a salt thereof (sodium salt, ammonium salt, or the like), a polystyrene sulfonate ammonium salt, or a polystyrene sulfonate sodium salt.

Examples of the cationic surfactant include an alkylamine salt and a quaternary ammonium salt. Examples of the amphoteric surfactant include an alkyl betaine-based surfactant, and an amine oxide-based surfactant.

Further, examples of the nonionic surfactant include a sugar ester-based surfactant such as sorbitan fatty acid ester, a fatty acid ester-based surfactant such as polyoxyethylene resin acid ester, and an ether-based surfactant such as polyoxyethylene alkyl ether.

Among these, an ionic surfactant is preferably used, and cholate or deoxycholate is particularly suitably used.

In the thermoelectric conversion layer, a mass ratio of surfactant/CNT is preferably 5 or less, and more preferably 3 or less.

It is preferable that the mass ratio of surfactant/CNT is 5 or less from the viewpoint that a higher thermoelectric conversion performance or the like is obtained.

If necessary, the thermoelectric conversion layer formed of an organic material may contain an inorganic material such as SiO₂, TiO₂, Al₂O₃, or ZrO₂.

In a case where the thermoelectric conversion layer contains an inorganic material, a content of the inorganic material is preferably 20% by mass or less, and more preferably 10% by mass or less.

The p-type thermoelectric conversion layer 14p and the n-type thermoelectric conversion layer 16n may be formed by a known method. For example, the following method may be used.

First, a coating composition for forming a thermoelectric conversion layer containing a thermoelectric conversion material and required components such as a surfactant is prepared.

Next, the prepared coating composition which becomes a thermoelectric conversion layer is patterned and applied according to a thermoelectric conversion layer to be formed. The application of the coating composition may be performed by a known method such as a method using a mask or a printing method.

After the coating composition is applied, the coating composition is dried by a method according to the resin material, thereby forming the thermoelectric conversion layer. If necessary, after the coating composition is dried, the coating composition (resin material) may be cured by being irradiated with ultraviolet rays or the like.

In addition, the prepared coating composition which becomes the thermoelectric conversion layer is applied to the entire surface of the insulating substrate and dried, and then the thermoelectric conversion layer may be formed as a pattern by etching or the like.

In a case where a thermoelectric conversion layer is formed by using mainly CNT and a surfactant, it is preferable to form the thermoelectric conversion layer by forming the thermoelectric conversion layer with the coating composition, then immersing the thermoelectric conversion layer in a solvent for dissolving the surfactant or washing the thermoelectric conversion layer with a solvent for dissolving the surfactant and drying the thermoelectric conversion layer.

Thus, it is possible to form the thermoelectric conversion layer having a very small mass ratio of surfactant/CNT by removing the surfactant from the thermoelectric conversion layer and more preferably not containing the surfactant. The thermoelectric conversion layer is preferably formed as a pattern by printing.

As the printing method, various known printing methods such as screen printing, metal mask printing, and ink jetting can be used. In a case where the thermoelectric conversion layer is formed as a pattern by using a coating composition containing CNT, it is more preferable to use metal mask printing.

The printing conditions may be appropriately set according to the physical properties (solid content concentration, viscosity, and viscoelastic properties) of the coating composition used, the opening size of a printing plate, the number of openings, the opening shape, a printing area, and the like.

In a case where the p-type thermoelectric conversion layer 14p and the n-type thermoelectric conversion layer 16n are formed by using the above-described nickel or a nickel alloy, inorganic materials such as BiTe-based material, other than the formation methods using such coating compositions, a film forming method such as a sputtering method, a vapor deposition method, a chemical vapor deposition (CVD) method, a plating method, or an aerosol deposition method may be used to form the thermoelectric conversion layers.

The size of the p-type thermoelectric conversion layer 14p and the n-type thermoelectric conversion layer 16n may be appropriately set according to the size of the module 10, the width of the support 12, the size of the connection electrode 18, and the like. In the present invention, the size refers to a size of the support 12 in a plane direction.

As described above, the p-type thermoelectric conversion layer 14p and the n-type thermoelectric conversion layer 16n have the same length in the longitudinal direction. In addition, since the thermoelectric conversion layers are formed at fixed intervals, the p-type thermoelectric conversion layers 14p and the n-type thermoelectric conversion layers 16n are alternately formed at equal intervals.

The thickness of the p-type thermoelectric conversion layer 14p and the n-type thermoelectric conversion layer 16n may be appropriately set according to the material for forming the thermoelectric conversion layers, and the like and is preferably 1 to 50 μm and more preferably 3 to 30 μm.

It is preferable to set the thickness of the p-type thermoelectric conversion layer 14p and the n-type thermoelectric conversion layer 16n to be in the above range from the viewpoint of obtaining good electrical conductivity and good printability, and the like.

The thickness of the p-type thermoelectric conversion layer 14p and the thickness of the n-type thermoelectric conversion layer 16n may be the same or different from each other but are basically the same.

In addition, the thickness of the p-type thermoelectric conversion layer 14p and the n-type thermoelectric conversion layer 16n is preferably thinner than the thickness of the connection electrode 18.

By adopting such a configuration, in a case where the module 10 having a bellows-like shape is compressed in the longitudinal direction, the p-type thermoelectric conversion layer 14p and the n-type thermoelectric conversion layer 16n are not easily brought into contact with each other.

In the module 10, the connection electrode 18 is formed on the surface of the support 12 on which the p-type thermoelectric conversion layer 14p and the n-type thermoelectric conversion layer 16n are formed.

The connection electrode 18 is provided for electrically connecting the p-type thermoelectric conversion layer 14p and the n-type thermoelectric conversion layer 16n, which are alternately formed in the longitudinal direction, in series. As described above, in the examples shown in the drawing, the thermoelectric conversion layers having a fixed length are formed at fixed intervals in the longitudinal direction. Accordingly, the connection electrodes 18 having a fixed length are formed at fixed intervals.

In the module 10 of the present invention, the length and intervals of the p-type thermoelectric conversion layers 14p, the n-type thermoelectric conversion layers 16n, and the connection electrodes 18 in the longitudinal direction are not necessarily fixed and different length and forming intervals may be present between the thermoelectric conversion layers and between the connection electrodes 18.

As the material for forming the connection electrode 18, as long as the material has a required conductivity, various conductive materials can be used for electrode formation.

Specific examples thereof include metal materials such as copper, silver, gold, platinum, nickel, aluminum, constantan, chromium, indium, iron, and copper alloy, and materials used for transparent electrodes in various devices, such as indium tin oxide (ITO) and zinc oxide (ZnO). Among these, copper, gold, silver, platinum, nickel, copper alloy, aluminum, constantan, and the like are preferably used, and copper, gold, silver, platinum, and nickel are more preferably used.

In addition, the connection electrode 18 may be a laminated electrode having a configuration in which a copper layer is formed on a chromium layer or the like.

In a case where the connection electrode and the metal layer are separately formed, all known metal materials can be used as the material for forming the metal layer and the above-described metal materials may be suitably used.

The size of the connection electrode 18 may be appropriately set according to the size of the module 10, the width of the support 12, the size of the p-type thermoelectric conversion layer 14p and the n-type thermoelectric conversion layer 16n, and the like.

Regarding the thickness of the connection electrode 18, a thickness at which sufficient conductivity for the p-type thermoelectric conversion layer 14p and the n-type thermoelectric conversion layer 16n can be obtained may be appropriately set according to the forming material.

Here, the connection electrode 18 is mountain-folded or valley-folded together with the support 12 in a case where the module 10 is formed in a bellows structure. By the plastic deformation of the connection electrode 18, the module 10 can be suitably maintained in a bellows-like folded state.

From the viewpoint of being capable of maintaining the module 10 in the bellows-like folded state, securing sufficient conductivity as an electrode, and the like, the thickness of the connection electrode 18 is preferably 3 μm or more and more preferably 6 μm or more. Further, the thickness of the connection electrode 18 is preferably thicker than the thickness of the support 12.

In the connection electrodes 18, low rigidity portions parallel to the width direction may be formed at the mountain fold position and at the valley fold position.

The low rigidity portion is a portion having lower rigidity than other portions in the connection electrode 18, that is, a portion which is more easily folded than other portions.

For example, the low rigidity portions to be formed in the connection electrode 18 are constituted by broken lines parallel to the width direction. In other words, the low rigidity portions can be formed in the connection electrode 18 by alternately forming a portion provided with an electrode (metal) and a portion not provided with an electrode in the width direction.

Alternatively, the thickness of the electrode (metal) at the position where the low rigidity portion is formed may be made thinner than the thickness of other portions and formed in a groove-like shape.

In this manner, by providing the low rigidity portion having rigidity lower than that of other regions to be parallel to the width direction, the connection electrode 18 can be selectively folded at the low rigidity portion. In addition, the positions of the top portions of the mountain fold portions and the bottom portions of the valley fold portions can be aligned in all of the connection electrodes 18.

Accordingly, the interval between the low rigidity portions in the longitudinal direction may be appropriately set according to the height required for the module 10 having a bellows structure or the like. In contrast, in a case where the height of the module 10 is limited, the interval between the low rigidity portions in the longitudinal direction may be set according to the limit of the height, and the size of the connection electrode 18, the p-type thermoelectric conversion layer 14p and the n-type thermoelectric conversion layer 16n in the longitudinal direction may be set according to the interval between the low rigidity portions.

The height of the module 10 is the size of the module 10 in the vertical direction in FIG. 1, that is, the size of the module 10 in a direction in which a temperature gradient is generated.

A method of forming the connection electrode 18 is not limited and a known forming method may be appropriately used according to the kind of material for forming the connection electrode 18 or the like. For example, the connection electrodes 18 having a fixed length can be formed at fixed intervals in the longitudinal direction by preparing a laminate in which a metal film such as copper foil is formed over the entire surface of the support 12 and removing an unnecessary metal film by etching.

The formation of the connection electrode 18 by etching of the metal film may be performed by a known method. For example, a method of removing a metal film by ablation with a laser beam, a method of performing etching by photolithography, and the like may be used.

Alternatively, the connection electrode 18 may be formed by using a normal resin film or the like as the support 12 and performing sputtering or vacuum vapor deposition on the surface of the support 12 by printing or the like.

In addition, after the thermoelectric conversion layers are formed on the support 12 on which the connection electrode 18 is formed, an auxiliary electrode may be formed on a connection surface between the thermoelectric conversion layer and the connection electrode 18. The auxiliary electrode may be formed by vacuum vapor deposition of metal or may be formed by printing using a conductive ink such as a silver paste.

As described above, the thermoelectric conversion device 100 has a configuration in which two modules 10 having a bellows structure as described above are provided and laminated in the height direction of the module 10. In addition, the valley fold portions V of the module 10a of the upper stage and the mountain fold portions M of the module 10b of the lower stage are overlapped as viewed from the folding direction of the bellows structure. In addition, the module 10a of the upper stage and the module 10b of the lower stage are laminated to be matched with the direction in which a temperature gradient is generated.

Accordingly, since the low temperature side of the module 10a of the upper stage and the high temperature side of the module 10b of the lower stage are overlapped and thermally connected to each other, or since the high temperature side of the module 10a of the upper stage and the low temperature side of the module 10b of the lower stage are overlapped and thermally connected to each other, a temperature difference obtained by adding a temperature difference by the module 10a of the upper stage and a temperature difference by the module 10b of the lower stage can be generated for the thermoelectric conversion device 100.

Here, simply with the configuration in which the thermoelectric conversion modules having a bellows structure are laminated, the contact area between the lower end portion (valley fold portion) of the module of the upper stage and the upper end portion (mountain fold portion) of the module of the lower stage is reduced. Thus, heat transfer efficiency is poor and a sufficient temperature difference cannot be obtained.

In addition, even in a configuration in which the contact area between the module of the upper stage and the module of the lower stage is secured by sandwiching a heat conduction plate or the like therebetween, a temperature loss is generated and thus a sufficient temperature difference cannot also be obtained.

In contrast, the thermoelectric conversion device 100 of the present invention has a configuration in which two thermoelectric conversion modules 10 which are formed in a bellows structure by being alternately mountain-folded or valley-folded at the position of the connection electrode 18 between the p-type thermoelectric conversion layer 14p and the n-type thermoelectric conversion layer 16n adjacent to each other are provided and the mountain fold portion M of the thermoelectric conversion module 10b of the lower stage and the valley fold portion V of the thermoelectric conversion module 10a of the upper stage are laminated in a direction in which a temperature gradient is generated so as to be overlapped with each other as viewed from the folding direction of the bellows structure.

Therefore, in the thermoelectric conversion device 100 of the present invention, the contact area between the valley fold portion V of the module 10a of the upper stage and the mountain fold portion M of the module 10b of the lower stage can be increased. In addition, since the connection electrodes 18 are arranged in the mountain fold portion M and the valley fold portion V overlapped with each other as viewed from the folding direction and the surfaces of the modules face to each other at the positions where the connection electrodes 18 are formed, the heat transfer efficiency of the module 10a of the upper stage and the module 10b of the lower stage can be increased. In addition, since the valley fold portion V of the module 10a of the upper stage and the mountain fold portion M of the module 10b of the lower stage are overlapped in a direction orthogonal to the direction in which a temperature gradient is generated, a temperature loss can be reduced.

Accordingly, in the thermoelectric conversion device 100 of the present invention, a temperature loss is reduced at the overlapped position and thus a sufficient temperature difference can be obtained.

In addition, in the module 10 used in for the thermoelectric conversion device 100, all of the p-type thermoelectric conversion layer 14p, the n-type thermoelectric conversion layer 16n, and the connection electrode 18 are formed on the support 12. Therefore, in a case where the module is formed in a bellows structure, or a case where two modules 10 are overlapped with each other, there is no risk of damage and mechanical strength can be increased.

Here, in the lower stage in the thermoelectric conversion device 100 shown in FIG. 1, in the connection electrodes 18 formed on one end portion side (the end portion side on the left side in the drawing) in the module 10a of the upper stage and the module 10b are electrically connected. That is, the module 10a of the upper stage and the module 10b of the lower stage are connected in series.

However, there is no limitation thereto. The module 10a of the upper stage and the module 10b of the lower stage may be electrically connected in parallel or the module 10a of the upper stage and the module 10b of the lower stage may be electrically independent.

In addition, the thermoelectric conversion device 100 shown in the example of the drawing has a configuration in which two modules 10 are laminated but is not limited thereto. The thermoelectric conversion device may have a configuration in which three or more modules 10 are laminated in a direction in which a temperature gradient is generated.

For example, in a case of the configuration in which three modules are laminated, a configuration in which mountain fold portions M of a module 10 of a lower stage and valley fold portions V of a module 10 of a middle stage are laminated so as to be overlapped with each other as viewed from the folding direction of a bellows structure, and mountain fold portions M of the module 10 of the middle stage and valley fold portions V of a module 10 of an upper stage are laminated so as to be overlapped with each other as viewed from the folding direction of the bellows structure may be adopted.

In addition, the thermoelectric conversion device 100 shown in FIG. 1 has a configuration in which the modules are laminated such that a surface the of the module 10a of the upper stage on the side on which the thermoelectric conversion layer and the connection electrode 18 are not formed, and a surface of the module 10b of the lower stage on the side on which the thermoelectric conversion layer and the connection electrode 18 are formed are in contact with each other. However, there is no limitation thereto. Any configuration in which the module 10a of the upper stage and the module 10b of the lower stage are not short-circuited to each other may be adopted. For example, a configuration in which the modules are laminated such that a surface of the module 10a of the upper stage on the side on which the thermoelectric conversion layer and the connection electrode 18 are formed and a surface of the module 10b of the lower stage on the side on which the thermoelectric conversion layer and the connection electrode 18 are not formed are in contact with each other may be adopted. Alternatively, a configuration in which the modules are laminated such that the surface of the module 10a of the upper stage on the side on which the thermoelectric conversion layer and the connection electrode 18 are not formed and the surface of the module 10b of the lower stage on the side on which the thermoelectric conversion layer and the connection electrode 18 are not formed are in contact with each other may be adopted.

Here, it is preferable that the thermoelectric conversion device of the present invention has a pressing member which presses overlapped portions of the mountain fold portions of the thermoelectric conversion module of the lower stage and the valley fold portions of the thermoelectric conversion module of the upper stage in the folding direction.

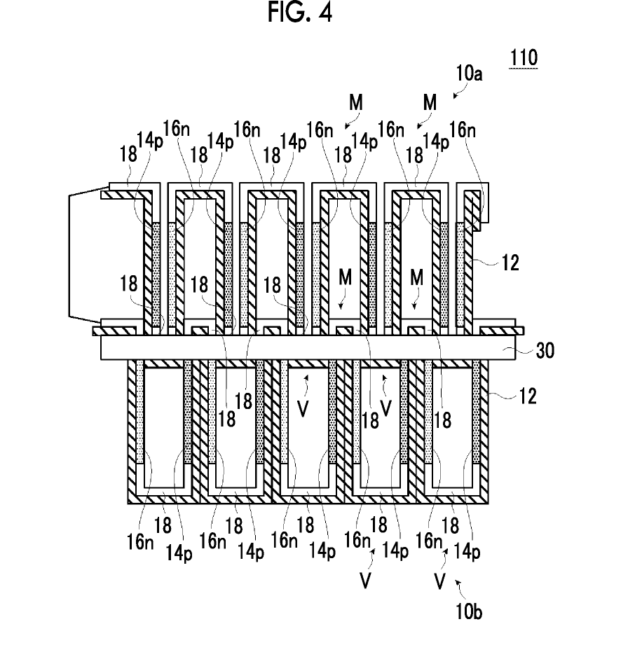

FIG. 4 shows another example of the thermoelectric conversion device of the present invention.

A thermoelectric conversion device 110 shown in FIG. 4 has the same configuration as the thermoelectric conversion device 100 shown in FIG. 1 except that a frame 30 is provided. Thus, the same numerical references are assigned to the same portions and different portions are mainly described below.

The thermoelectric conversion device 110 shown in FIG. 4 has a module 10a of an upper stage, a module 10b of a lower stage, and a frame 30.

The frame 30 is a pressing member which presses overlapped portions of mountain fold portions M of the module 10b of the lower stage and valley fold portions V of the module 10a of the upper stage in the folding direction. The pressing member may be also referred to as a fixing member which fixes the module 10a of the upper stage and the module 10b of the lower stage.

The configuration of the frame 30 is not limited as long as the overlapped portion of two modules can be pressed. For example, the frame 30 may have a configuration in which two rod-like members are respectively arranged at both end portions of the thermoelectric conversion device 110 in the folding direction and the two rod-like members are fixed by screws.

The material of the frame 30 is also not limited and various resins and metals can be appropriately used. Regarding the frame 30, in a case where the connection electrode 18 and the thermoelectric conversion layer come into contact with each other, the frame 30 preferably has insulating properties.

In addition, the size of the frame 30 is also not limited and may be appropriately set according to the size of the overlapped portion of the two modules.

The configuration having the pressing member is preferable because the module 10a of the upper stage and the module 10b of the lower stage can be reliably fixed in a state in which the mountain fold portions M of the module 10b of the lower stage and the valley fold portions V of the module 10a of the upper stage are overlapped with each other as viewed from the folding direction.

In addition, by pressing the overlapped portions of the mountain fold portions M of the module 10b of the lower stage and the valley fold portions V of the module 10a of the upper stage by the pressing member in the folding direction, the mountain fold portions M of the module 10b of the lower stage and the valley fold portions V of the module 10a of the upper stage can be reliably brought into contact with each other. Thus, heat transfer efficiency can be further increased.

Here, in the thermoelectric conversion device 110 shown in FIG. 4, the pressing member which presses the overlapped portions of the two modules is not limited to the above-described frame 30, and any pressing member may be used as long as the pressing member can press the overlapped portions of the two modules in the folding direction.

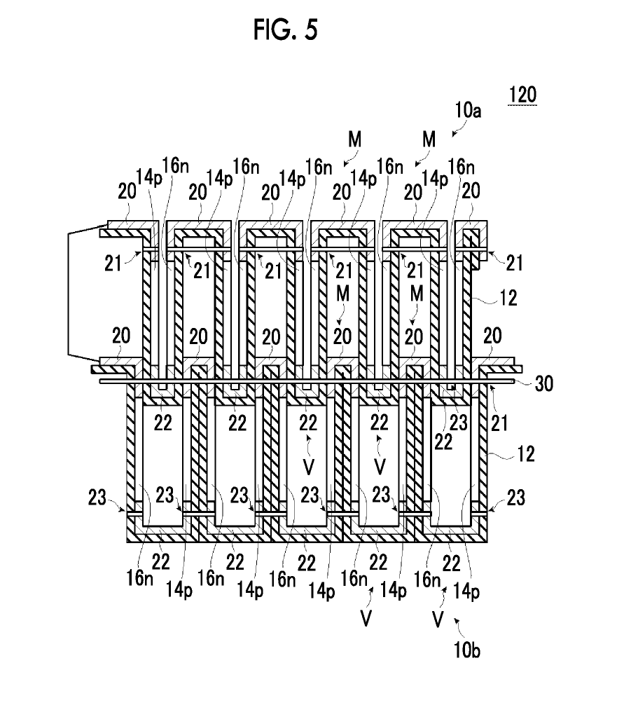

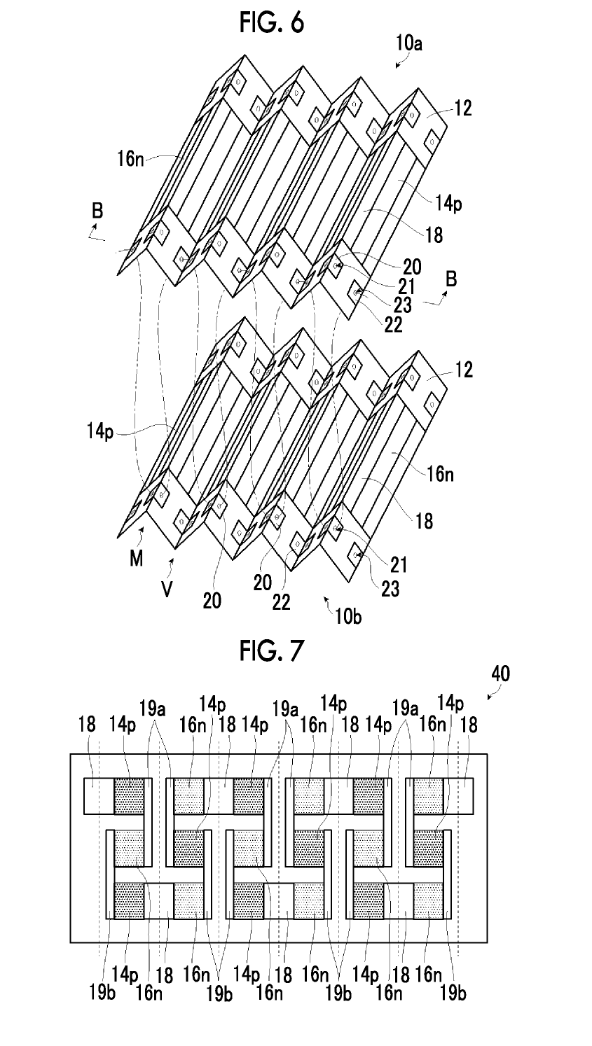

FIG. 5 is a cross-sectional view schematically showing still another example of the thermoelectric conversion device according to the present invention, and FIG. 6 is a schematic perspective view for illustrating the thermoelectric conversion device in FIG. 5. FIG. 5 is a a cross-sectional view showing a thermoelectric conversion device 120 taken along line B-B after two modules 10 shown in FIG. 6 are laminated.

The thermoelectric conversion device 120 shown in FIG. 5 has the same configuration as the thermoelectric conversion device 100 shown in FIG. 1 except that metal layers 20, through-holes 21, metal layers 22, and through-holes 23 are formed in the module 10 and a wire 32 is provided. Thus, the same numerical references are assigned to the same portions and different portions are mainly described below.

As shown in FIGS. 5 and 6, the module 10 used in the thermoelectric conversion device 120 has metal layers 20 and 22 provided to be separated from connection electrodes 18 in the longitudinal direction of a support 12 at the same positions as the positions of the connection electrodes 18 in both end portions of the support 12 in the width direction, and through-holes 21 which pass through the metal layers 20 and the support 12, and through-holes 23 which pass through the metal layers 22 and the support 12 are respectively formed.

As shown in FIG. 5, the metal layer 20 is arranged on the mountain fold portion M side and the metal layer 22 is arranged on the valley fold portion V side in a case where the module 10 is folded to form a bellows structure. In addition, the metal layers 20 and 22 are respectively formed in all of the mountain fold portions M and the valley fold portions V. At the positions of the metal layers 20 in all of the mountain fold portions M, the through-holes 21 are formed and at the positions of the metal layers 22 in all of the valley fold portions V, the through-holes 23 are formed.

The wire 32 is pressing member which is inserted into the through-holes 23 of the module 10a of the upper stage and the through-holes 21 of the module 10b of the lower stage in the overlapped portions of the mountain fold portions M of the module 10b of the lower stage and the valley fold portions V of the module 10a of the upper stage, and presses the overlapped portions in the folding direction.

As indicated by a dashed line in FIG. 6, the wire 32 is alternately inserted into the through-holes 23 formed in the valley fold portions V of the module 10a of the upper stage and the through-holes 21 formed in the mountain fold portions M of the module 10b of the lower stage.

As described above, a configuration in which the wire 32 as a pressing member is inserted into the through-holes formed in the overlapped portions of the module 10 and the module is fastened by the wire 32 to press the overlapped portions of the module may be adopted.

In addition, the configuration of pressing the module with the wire 32 can impart flexibility to the thermoelectric conversion device 120.

The material of the wire 32 is not limited and various resins, metals, thread-like materials obtained by twisting fibers, and the like can be used.

In addition, the thickness and length of the wire 32 are not limited and may be appropriately set according to the size and configuration of the module 10.

In the example shown in FIG. 5, the configuration in which the metal layer is provided at the position for forming the through-hole is used but is not limited thereto. A configuration in which the through-holes 21 and 23 are provided in the support 12 without providing the metal layers may be adopted.

The thermoelectric conversion device may have a configuration in which the material for forming the thermoelectric conversion layer of the module 10a of the upper stage and the material for forming the thermoelectric conversion layer of the module 10b of the lower stage are different from each other.

For example, a configuration in which in the module 10a of the upper stage and the module 10b of the lower stage, materials having different temperature properties are used as materials for forming the thermoelectric conversion layers may be adopted. Thus, a temperature gradient can be effectively generated in the respective temperature ranges of the module 10a of the upper stage and the module 10b of the lower stage, and a larger temperature difference can be provided.

In addition, by adopting the configuration in which materials having different temperature properties are as materials for forming the thermoelectric conversion layers in the module 10a of the upper stage and the module 10b of the lower stage, even in a case where the thermoelectric conversion device is as a power generation element, power generation can be effectively performed in the respective temperature ranges of the module 10a of the upper stage and the module 10b of the lower stage, and thermoelectric conversion efficiency can be further increased.

In the example shown in the drawing, the size of the thermoelectric conversion element (thermoelectric conversion layer and connection electrode 18) of the module 10a of the upper stage and the size of the thermoelectric conversion element of the module 10b of the lower stage are the same. However, there is no limitation thereto. In the module 10a of the upper stage and the module 10b of the lower stage, the sizes of the thermoelectric conversion elements may be different from each other.

In addition, the number of folds of the bellows structures of the module 10a of the upper stage and the module 10b of the lower stage is the same. However, there is no limitation thereto. The number of folds of the bellows structures of the module 10a of the upper stage and the module 10b of the lower stage may be different from each other.

In the above-described embodiments, the module 10 has the configuration in which the p-type thermoelectric conversion layers 14p and the n-type thermoelectric conversion layers 16n are alternately arranged at predetermined intervals in the longitudinal direction of the long support 12, and the connection electrode 18 is arranged between the p-type thermoelectric conversion layer 14p and the n-type thermoelectric conversion layer 16n adjacent to each other, that is, the configuration in which the p-type thermoelectric conversion layer 14p, the n-type thermoelectric conversion layer 16n, and the connection electrode 18 are arranged in a predetermined pattern in one direction. However, there is no limitation thereto.

FIG. 7 is a top view for illustrating still another example of the thermoelectric conversion module. In FIG. 7, the same reference numerals are assigned to the same structures as in the thermoelectric conversion module 10 shown in FIGS. 2A to 2D and the detailed description thereof is omitted.

A thermoelectric conversion module 40 shown in FIG. 7 has one or more p-type thermoelectric conversion layers 14p and one or more n-type thermoelectric conversion layers 16n arranged in a direction orthogonal to the folding direction in each region between adjacent mountain and valley folds of a support 12. In FIG. 7, the position indicated by a broken line is a position where a mountain fold or a valley fold is formed. For example, the broken line on the left side in FIG. 7 is at the position of the mountain fold and a valley fold and a mountain fold are alternately repeated at the position of each broken line sequentially toward the right side.

Specifically, in the thermoelectric conversion module 40, in one region (first region) between adjacent mountain and valley folds on one end portion side of the support 12 (the left side in FIG. 7) in a direction orthogonal to the folding direction, that is, the width direction of the support 12, the p-type thermoelectric conversion layer 14p, the n-type thermoelectric conversion layer 16n, and the p-type thermoelectric conversion layer 14p are arranged in this order.

In addition, the p-type thermoelectric conversion layer 14p of the upper side in FIG. 7 and the n-type thermoelectric conversion layer 16n adjacent to the p-type thermoelectric conversion layer 14p are electrically connected by a connection electrode 19a on the valley fold side. The connection electrode 19a extends in the width direction of the support 12 and is connected to the end portions of the p-type thermoelectric conversion layer 14p and the n-type thermoelectric conversion layer 16n on the valley fold side.

In addition, a connection electrode 18 is connected to the end portion of the p-type thermoelectric conversion layer 14p of the upper side in FIG. 7 on the mountain fold side.

In addition, the n-type thermoelectric conversion layer 16n and the p-type thermoelectric conversion layer 14p of the lower side in FIG. 7 adjacent to the n-type thermoelectric conversion layer 16n are electrically connected by a connection electrode 19b on the mountain fold side. The connection electrode 19b extends in the width direction of the support 12 and is connected to the end portions of the n-type thermoelectric conversion layer 16n and the p-type thermoelectric conversion layer 14p on the mountain fold side.

The end portion of the p-type thermoelectric conversion layer 14p of the lower side in FIG. 7 on the valley fold side is connected to the n-type thermoelectric conversion layer 16n adjacent to the p-type thermoelectric conversion layer in the longitudinal direction of the support by the connection electrode 18.

Next, the n-type thermoelectric conversion layer 16n, p-type thermoelectric conversion layer 14p, and the n-type thermoelectric conversion layer 16n are arranged in this order in the width direction of the support 12 from one end portion side of the support 12 (the left side in FIG. 7) to a second region (one region between adjacent mountain and valley folds).

In addition, the n-type thermoelectric conversion layer 16n of the upper side in FIG. 7 and the p-type thermoelectric conversion layer 14p adjacent to the n-type thermoelectric conversion layer 16n are electrically connected by the connection electrode 19a on the valley fold side. The connection electrode 19a extends in the width direction of the support 12 and is connected to the end portions of the n-type thermoelectric conversion layer 16n and the p-type thermoelectric conversion layer 14p on the valley fold side.

The end portion of the n-type thermoelectric conversion layer 16n of the lower side in FIG. 7 on the valley fold side is connected to the p-type thermoelectric conversion layer 14p in the first region, which is adjacent to the n-type thermoelectric conversion layer 16n in the longitudinal direction of the support, by the connection electrode 18.

The p-type thermoelectric conversion layer 14p and the n-type thermoelectric conversion layer 16n of the lower side in FIG. 7 adjacent to the p-type thermoelectric conversion layer 14p are electrically connected by the connection electrode 19b on the mountain fold side. The connection electrode 19b extends in the width direction of the support 12 and is connected to the end portions of the p-type thermoelectric conversion layer 14p and the n-type thermoelectric conversion layer 16n on the mountain fold side.

The end portion of the n-type thermoelectric conversion layer 16n of the upper side in FIG. 7 on the mountain fold side is connected to the p-type thermoelectric conversion layer 14p in a third region, which is adjacent to the n-type thermoelectric conversion layer 16n in the longitudinal direction of the support, by the connection electrode 18.

The thermoelectric conversion module 40 has a configuration in which by repeating such a configuration, a plurality of p-type thermoelectric conversion layers 14p and n-type thermoelectric conversion layers 16n are alternately arranged in the width direction of the support 12 in each region between adjacent mountain and valley folds and on the support 12, thermoelectric conversion layers adjacent to each other in the width direction are connected by the connection electrode 19, and further, the p-type thermoelectric conversion layer 14p and the n-type thermoelectric conversion layer 16n are connected by the connection electrode 18 in any one end portion between each region in the width direction.

Thus, the plurality of p-type thermoelectric conversion layers 14p and n-type thermoelectric conversion layers 16n are alternately connected in series. Accordingly, a temperature difference can be generated between the valley fold portion and the mountain fold portion by applying a current to the thermoelectric conversion module 40.

In the example shown in FIG. 7, in the region between adjacent mountain and the valley folds of the support 12 (hereinafter, also referred to as “sloped portion”), the number of thermoelectric conversion layers to be arranged in the width direction was 3. However, the number of thermoelectric conversion layers is not limited thereto and may be 2 or 4 or more.

However, from the viewpoint of electric connection from the thermoelectric conversion layer in one sloped portion of the bellows to the thermoelectric conversion layer of an adjacent sloped portion over the electrode at the mountain portion, it is preferable that the number of thermoelectric conversion layers in one sloped portion is odd.

While the thermoelectric conversion device of the present invention has been described above, the present invention is not limited to the above-described examples and various improvements and modifications may of course be made without departing from the spirit of the present invention.

### EXPLANATION OF REFERENCES

10, 10a, 10b, 40: thermoelectric conversion module

12: support

14p: p-type thermoelectric conversion layer

16n: n-type thermoelectric conversion layer

18, 19a, 19b: connection electrode

20, 22: metal layer

21, 23: through-hole

28: insulating sheet

30: frame

32: wire

100, 110, 120 thermoelectric conversion device

What is claimed is:

1. A thermoelectric conversion device comprising:
a plurality of thermoelectric conversion modules each of which has an insulating support having flexibility, a plurality of p-type thermoelectric conversion layers and n-type thermoelectric conversion layers which are alternately formed on one surface of the support with intervals, and connection electrodes each of which electrically connects the p-type thermoelectric conversion layer and the n-type thermoelectric conversion layer adjacent to each other, and is formed in a bellows structure by being alternately mountain-folded or valley-folded at a position of the connection electrode between the p-type thermoelectric conversion layer and the n-type thermoelectric conversion layer adjacent to each other in one direction,
wherein the plurality of thermoelectric conversion modules are laminated such that mountain fold portions of one thermoelectric conversion module and valley fold portions of a thermoelectric conversion module adjacent to the one thermoelectric conversion module are overlapped with each other as viewed from a folding direction of the bellows structure.

2. The thermoelectric conversion device according to claim 1,
wherein the laminated thermoelectric conversion modules are laminated such that the connection electrodes of the mountain fold portions of the thermoelectric conversion module of a lower stage and the connection electrodes of the valley fold portions of the thermoelectric conversion module of an upper stage are overlapped with each other as viewed from the folding direction.

3. The thermoelectric conversion device according to claim 1, further comprising:
a pressing member which presses overlapped portions of the mountain fold portions of the thermoelectric conversion module of the lower stage and the valley fold portions of the thermoelectric conversion module of the upper stage of the laminated thermoelectric conversion modules in the folding direction.

4. The thermoelectric conversion device according to claim 2, further comprising:
a pressing member which presses overlapped portions of the mountain fold portions of the thermoelectric conversion module of the lower stage and the valley fold portions of the thermoelectric conversion module of the upper stage of the laminated thermoelectric conversion modules in the folding direction.

5. The thermoelectric conversion device according to claim 3,
wherein the pressing member is a frame-like member.

6. The thermoelectric conversion device according to claim 4,
wherein the pressing member is a frame-like member.

7. The thermoelectric conversion device according to claim 3,
wherein the plurality of thermoelectric conversion modules respectively have through-holes in the overlapped portions,
the pressing member is a wire-like member, and
the wire-like member is inserted into the through-holes of the plurality of thermoelectric conversion modules.

8. The thermoelectric conversion device according to claim 4,
wherein the plurality of thermoelectric conversion modules respectively have through-holes in the overlapped portions,
the pressing member is a wire-like member, and
the wire-like member is inserted into the through-holes of the plurality of thermoelectric conversion modules.

9. The thermoelectric conversion device according to claim 1,
wherein a material for forming a thermoelectric conversion layer of the thermoelectric conversion module of the upper stage and a material for forming a thermoelectric conversion layer of the thermoelectric conversion module of the lower stage have different temperature properties.

10. The thermoelectric conversion device according to claim 6,
wherein a material for forming a thermoelectric conversion layer of the thermoelectric conversion module of the upper stage and a material for forming a thermoelectric conversion layer of the thermoelectric conversion module of the lower stage have different temperature properties.

11. The thermoelectric conversion device according to claim 8,
wherein a material for forming a thermoelectric conversion layer of the thermoelectric conversion module of the upper stage and a material for forming a thermoelectric conversion layer of the thermoelectric conversion module of the lower stage have different temperature properties.

12. The thermoelectric conversion device according to claim 1,
wherein the thermoelectric conversion module has the support which is long, a plurality of p-type thermoelectric conversion layers and n-type thermoelectric conversion layers which are alternately formed on one surface of the support with intervals in a longitudinal direction of the support, and connection electrodes each of which electrically connects the p-type thermoelectric conversion layer and the n-type thermoelectric conversion layer adjacent to each other in the longitudinal direction of the support, and is formed in a bellows structure by being alternately mountain-folded or valley-folded at the position of the connection electrode between the p-type thermoelectric conversion layer and the n-type thermoelectric conversion layer adjacent to each other.

13. The thermoelectric conversion device according to claim 10,
wherein the thermoelectric conversion module has the support which is long, a plurality of p-type thermoelectric conversion layers and n-type thermoelectric conversion layers which are alternately formed on one surface of the support with intervals in a longitudinal direction of the support, and connection electrodes each of which electrically connects the p-type thermoelectric conversion layer and the n-type thermoelectric conversion layer adjacent to each other in the longitudinal direction of the support, and is formed in a bellows structure by being alternately mountain-folded or valley-folded at the position of the connection electrode between the p-type thermoelectric conversion layer and the n-type thermoelectric conversion layer adjacent to each other.

14. The thermoelectric conversion device according to claim 11,
wherein the thermoelectric conversion module has the support which is long, a plurality of p-type thermoelectric conversion layers and n-type thermoelectric conversion layers which are alternately formed on one surface of the support with intervals in a longitudinal direction of the support, and connection electrodes each of which electrically connects the p-type thermoelectric conversion layer and the n-type thermoelectric conversion layer adjacent to each other in the longitudinal direction of the support, and is formed in a bellows structure by being alternately mountain-folded or valley-folded at the position of the connection electrode between the p-type thermoelectric conversion layer and the n-type thermoelectric conversion layer adjacent to each other.

15. The thermoelectric conversion device according to claim 1,
wherein in the thermoelectric conversion module, one or more p-type thermoelectric conversion layers and one or more n-type thermoelectric conversion layers are arranged in a region between adjacent mountain and valley folds in a direction orthogonal to the folding direction.

16. The thermoelectric conversion device according to claim 13,
wherein in the thermoelectric conversion module, one or more p-type thermoelectric conversion layers and one or more n-type thermoelectric conversion layers are arranged in a region between adjacent mountain and valley folds in a direction orthogonal to the folding direction.

17. The thermoelectric conversion device according to claim 14,
wherein in the thermoelectric conversion module, one or more p-type thermoelectric conversion layers and one or more n-type thermoelectric conversion layers are arranged in a region between adjacent mountain and valley folds in a direction orthogonal to the folding direction.
